(19) United States
(12) Patent Application Publication
(10) Pub. No.: US 2015/0145042 A1
(43) Pub. Date: May 28, 2015

(54) TRANSISTORS HAVING MULTIPLE LATERAL CHANNEL DIMENSIONS

(71) Applicant: International Business Machines Corporation, Armonk, NY (US)

(72) Inventors: Huiming Bu, Milwood, NY (US); Terence B. Hook, Jericho, VT (US); Effendi Leobandung, Stormville, NY (US); Theodorus E. Standaert, Clifton Park, NY (US)

(73) Assignee: International Business Machines Corporation, Armonk, NY (US)

(21) Appl. No.: 14/088,480

(22) Filed: Nov. 25, 2013

(51) Int. Cl. H01L 27/12; H01L 21/3105; H01L 21/02; H01L 21/8234; H01L 29/66

(52) U.S. Cl. CPC H01L 27/1211; H01L 21/823431; H01L 29/6681; H01L 29/66818; H01L 21/02164; H01L 21/31055; H01L 21/02238; H01L 21/02255; H01L 21/02252
USPC 257/347; 438/197

(57) ABSTRACT

Fin field effect transistors or semiconductor nanowire field effect transistors having different lateral channel dimensions can be formed by providing multiple disposable gate structures, removing one type of disposable gate structures while masking at least another type of disposable gate structures, thinning physically exposed semiconductor material portions by oxidation and an oxide etch, repeatedly performing the thinning process for any additional type of disposable gate structures, and filling gate cavities with replacement gate structures. Field effect transistors having different lateral channel dimensions can provide different threshold voltages and other device characteristics to provide a variety of field effect transistors on a same semiconductor substrate.

### BACKGROUND

The present disclosure generally relates to semiconductor devices, and particularly to field effect transistors having different lateral channel dimensions, and methods of manufacturing the same.

Fin field effect transistors and semiconductor nanowire field effect transistors are typically formed by sidewall image transfer (SIT) processes to enable lateral dimensions less than a minimum lateral dimension that can be printed by lithographic methods. Since the thickness of a material layer employed to form sidewall structures is uniform, the lateral dimensions of the semiconductor fins or semiconductor nanowires formed by the sidewall image transfer process are the same throughout the entire area of a substrate. Thus, while different lateral channel dimensions in fin field effect transistors and semiconductor nanowire field effect transistors can be useful in providing different threshold voltages, it is difficult to form field effect transistors including semiconductor fins or semiconductor nanowires having different sublithographic dimensions on a same substrate.

### SUMMARY

Fin field effect transistors or semiconductor nanowire field effect transistors having different lateral channel dimensions can be formed by providing multiple disposable gate structures, removing one type of disposable gate structures while masking at least another type of disposable gate structures, thinning physically exposed semiconductor material portions by oxidation and an oxide etch, repeatedly performing the thinning process for any additional type of disposable gate structures, and filling gate cavities with replacement gate structures. Field effect transistors having different lateral channel dimensions can provide different threshold voltages and other device characteristics to provide a variety of field effect transistors on a same semiconductor substrate.

According to an aspect of the present disclosure, a method of forming a semiconductor structure is provided. A first semiconductor material portion and a second semiconductor material portion are formed on a substrate. A first disposable gate structure straddling the first semiconductor material portion and a second disposable gate structure straddling the second semiconductor material are formed. A planarization dielectric layer laterally surrounding the first disposable gate structure and the second disposable gate structure is formed. The first disposable gate structure is removed to form a gate cavity while the second disposable gate structure is not removed. A region of the first semiconductor material portion is physically exposed within the gate cavity. A sub-portion of the first semiconductor material portion is thinned within the gate cavity. The second disposable gate structure is removed. Gate dielectrics and gate electrodes are formed on the thinned region of the first semiconductor material portion and the second semiconductor material portion.

According to another aspect of the present disclosure, a semiconductor structure includes a first field effect transistor and a second field effect transistor that are located on a substrate. A channel region of the first field effect transistor has a first vertical cross-sectional shape that is invariant along a lengthwise direction of the channel region of the first field effect transistor. A channel region of the second field effect transistor has a second vertical cross-sectional shape that is invariant along a lengthwise direction of the channel region of the second field effect transistor. Each of a source region and a drain region of the first field effect transistor includes a pair of sidewalls that are laterally spaced from each other by a greater width than a maximum lateral dimension of the first channel region within the first vertical cross-sectional shape. Each of a source region and a drain region of the second field effect transistor includes another pair of sidewalls that are laterally spaced from each other by a same width as a maximum lateral dimension of the channel region of the second field effect transistor within the second vertical cross-sectional shape.

### BRIEF DESCRIPTION OF SEVERAL VIEWS OF THE DRAWINGS

FIG. 1A is a top-down view of a first exemplary semiconductor structure after formation of semiconductor fins according to a first embodiment of the present disclosure.

FIG. 1B is a vertical cross-sectional view of the first exemplary semiconductor structure of FIG. 1A along the vertical plane B-B′.

FIG. 2A is a top-down view of the first exemplary semiconductor structure after formation of disposable gate structures, gate spacers, and source and drain regions according to a first embodiment of the present disclosure.

FIG. 2B is a vertical cross-sectional view of the first exemplary semiconductor structure of FIG. 2A along the vertical plane B-B′.

FIG. 3A is a top-down view of a first exemplary semiconductor structure after formation of a planarization dielectric layer according to the first embodiment of the present disclosure.

FIG. 3B is a vertical cross-sectional view of the first exemplary semiconductor structure of FIG. 3A along the vertical plane B-B′.

FIG. 4A is a vertical cross-sectional view of the first exemplary semiconductor structure after forming and patterning of a mask layer, and removal of a first disposable gate structure to form a first gate cavity according to the first embodiment of the present disclosure.

FIG. 4B is a vertical cross-sectional view of the first exemplary semiconductor structure of FIG. 4A along the vertical plane B-B′.

FIG. 5A is a vertical cross-sectional view of the first exemplary semiconductor structure after oxidizing surface portion of first semiconductor fins within the first gate cavity according to the first embodiment of the present disclosure.

FIG. 5B is a vertical cross-sectional view of the first exemplary semiconductor structure of FIG. 5A along the vertical plane B-B′.

FIG. 6A is a vertical cross-sectional view of the first exemplary semiconductor structure after removal of the mask layer, a second disposable gate structure, and surface oxide portions on the first semiconductor fins according to the first embodiment of the present disclosure.

FIG. 6B is a vertical cross-sectional view of the first exemplary semiconductor structure of FIG. 6A along the vertical plane B-B′.

FIG. 7A is a vertical cross-sectional view of the first exemplary semiconductor structure after formation of replacement gate structures according to the first embodiment of the present disclosure.

FIG. 7B is a vertical cross-sectional view of the first exemplary semiconductor structure of FIG. 7A along the vertical plane B-B′.

FIG. 7C is a horizontal cross-sectional view of the first exemplary semiconductor structure of FIG. 7A along the horizontal plane C-C′ in FIG. 7B.

FIG. 8A is a top-down view of a second exemplary semiconductor structure after formation of semiconductor nanowires and semiconductor pads according to a second embodiment of the present disclosure.

FIG. 8B is a vertical cross-sectional view of the second exemplary semiconductor structure of FIG. 8A along the vertical plane B-B′.

FIG. 9A is a top-down view of a second exemplary semiconductor structure after suspending the semiconductor nanowires according to the second embodiment of the present disclosure.

FIG. 9B is a vertical cross-sectional view of the second exemplary semiconductor structure of FIG. 9A along the vertical plane B-B′.

FIG. 9C is a vertical cross-sectional view of the second exemplary semiconductor structure of FIG. 9A along the vertical plane C-C′.

FIG. 10A is a top-down view of the second exemplary semiconductor structure after formation of disposable gate structures, gate spacers, and source and drain regions according to the second embodiment of the present disclosure.

FIG. 10B is a vertical cross-sectional view of the second exemplary semiconductor structure of FIG. 10A along the vertical plane B-B′.

FIG. 11A is a top-down view of the second exemplary semiconductor structure after formation of a planarization dielectric layer, forming and patterning of a mask layer, and removal of a first disposable gate structure to form a first gate cavity according to the second embodiment of the present disclosure.

FIG. 11B is a vertical cross-sectional view of the second exemplary semiconductor structure of FIG. 11A along the vertical plane B-B′.

FIG. 12A is a vertical cross-sectional view of the second exemplary semiconductor structure after oxidizing surface portion of second semiconductor fins within the second gate cavity according to the second embodiment of the present disclosure.

FIG. 12B is a vertical cross-sectional view of the second exemplary semiconductor structure of FIG. 12A along the vertical plane B-B′.

FIG. 13A is a vertical cross-sectional view of the second exemplary semiconductor structure after removal of the mask layer, a second disposable gate structure, and surface oxide portions on the second semiconductor fins according to the second embodiment of the present disclosure.

FIG. 13B is a vertical cross-sectional view of the second exemplary semiconductor structure of FIG. 6A along the vertical plane B-B′.

FIG. 14A is a vertical cross-sectional view of the second exemplary semiconductor structure after formation of replacement gate structures according to the second embodiment of the present disclosure.

FIG. 14B is a vertical cross-sectional view of the second exemplary semiconductor structure of FIG. 7A along the vertical plane B-B′.

### DETAILED DESCRIPTION

As stated above, the present disclosure relates to field effect transistors having different lateral channel dimensions, and methods of manufacturing the same. Aspects of the present disclosure are now described in detail with accompanying figures. Like and corresponding elements are referred to by like reference numerals. Proportions of various elements in the accompanying figures are not drawn to scale. As used herein, ordinals such as “first” and “second” are employed merely to distinguish similar elements, and different ordinals may be employed to designate a same element in the specification and/or claims.

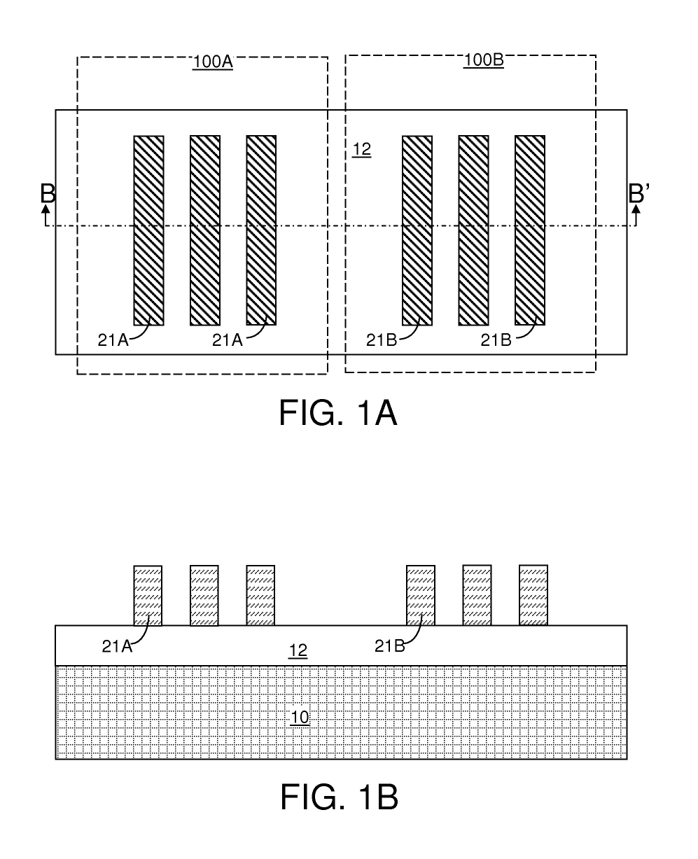

Referring to FIGS. 1A and 1B, a first exemplary semiconductor structure according to a first embodiment of the present disclosure includes a plurality of semiconductor material portions located on a substrate (10, 12). In one embodiment, the plurality of semiconductor material portions can be formed by providing a semiconductor-on-insulator (SOI) substrate including a vertical stack, from bottom to top, of a handle substrate 10, a buried insulator layer 12, and a top semiconductor layer, and by patterning the top semiconductor layer to form the plurality of semiconductor material portions. The top semiconductor layer can include a same semiconductor material throughout, or can include a plurality of regions including different semiconductor materials. Alternatively, a bulk semiconductor substrate can be employed in lieu of an SOI substrate to provide a plurality of semiconductor fins located on a semiconductor substrate, i.e., the remaining portion of the bulk semiconductor substrate excluding the plurality of semiconductor fins.

The first exemplary semiconductor structure can include various device regions. In a non-limiting illustrative example, the first exemplary semiconductor structure can include a first device region 100A and a second device region 100B. Additional device regions (not shown) can be provided for the purpose of forming additional devices. Further, multiple instances of devices can be formed in each of the device regions (100A, 100B). Each of the device regions (100A, 100B) includes at least one semiconductor fin. The first device region 100A can be employed to form a first fin field effect transistor, and the second device region 100B can be employed to form a second fin field effect transistor.

At least one first semiconductor material portion can be formed in the first device region 100A, and at least one second semiconductor material portion can be formed in the second device region 100B. In one embodiment, the at least one first semiconductor material portion can be at least one first semiconductor fin 21A, and the at least one second semiconductor material portion can be at least one second semiconductor fin 21B.

As used herein, a “semiconductor fin” refers to a semiconductor material portion having a pair of parallel vertical sidewalls that are laterally spaced by a uniform dimension. In one embodiment, each semiconductor fin can have a rectangular horizontal cross-sectional area such that the spacing between the pair of parallel vertical sidewalls is the same as the length of shorter sides of the shape of the rectangular horizontal cross-sectional area. As used herein, a “fin field effect transistor” refers to a field effect transistor in which at least a channel region is located within a semiconductor fin.

In one embodiment, each of the first and second semiconductor fins can have a rectangular horizontal cross-sectional shape bounded by a pair of lengthwise sidewalls and a pair of widthwise sidewalls. As used herein, a “lengthwise direction” of an element refers to a direction about which the moment of inertia of the element becomes a minimum. As used herein, a lengthwise sidewall of an element refers to a sidewall of an element that extends along the lengthwise direction of the element. As used herein, a widthwise sidewall of an element refers to a sidewall of the element that extends along a horizontal direction that is perpendicular to the lengthwise direction of the element.

In one embodiment, each of the device regions (100A, 100B) can include at least one semiconductor fin (21A or 21B). In one embodiment, the entirety of the each semiconductor fin (21A, 21B) can include a same single crystalline semiconductor material. The semiconductor material for the at least one semiconductor fin (21A or 21B) in each device region (100A, 100B) can be independently selected. In one embodiment, each semiconductor fin (21A or 21B) can include a same semiconductor material throughout the entirety of the semiconductor fin (21A or 21B). In one embodiment, each semiconductor material for any one of the semiconductor fins (21A, 21B) can be independently selected from single crystalline silicon, a single crystalline silicon-germanium alloy, a single crystalline silicon-carbon alloy, and a single crystalline silicon-germanium-carbon alloy. In one embodiment, the entirety of the top semiconductor layer can include a same single crystalline semiconductor material, and all of the semiconductor fins (21A, 21B) can include the same single crystalline semiconductor material.

In one embodiment, each semiconductor fin (21A or 21B) can include an intrinsic single crystalline semiconductor material. Alternately, one or more of the semiconductor fins (21A, 21B) can include a doped semiconductor material. In one embodiment, each of the at least one first semiconductor fin 21A in the first device region 100A can be intrinsic or can have a doping of a first conductivity type, and each of the at least one second semiconductor fin 21B in the second device region 100B can be intrinsic or can have a doping of a second conductivity type, which is the opposite of the first conductivity type. For example, the first conductivity type can be p-type and the second conductivity type can be n-type, or vice versa.

Each semiconductor fin (21A or 21B) can include a semiconductor material that is independently selected from silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. In one embodiment, each semiconductor fin (21A or 21B) can include a semiconductor material that is independently selected from single crystalline silicon, a single crystalline silicon-germanium alloy, a single crystalline silicon-carbon alloy, and a single crystalline silicon-germanium-carbon alloy. As used herein, a “semiconductor material” of an element refers to all elemental or compound semiconductor materials in the element excluding the electrical dopants therein. The semiconductor material within each semiconductor fin can be the same throughout the entirety of the semiconductor fin.

Each semiconductor fin (21A, 21B) can have a rectangular horizontal cross-sectional area. The width of each semiconductor fin (21A, 21B) can be in a range from 5 nm to 300 nm, although lesser and greater thicknesses can also be employed. The height of each semiconductor fin (21A, 21B) can be in a range from 30 nm to 600 nm, although lesser and greater thicknesses can also be employed. In one embodiment, the semiconductor fins (21A, 21B) can have a same width. In one embodiment, the semiconductor fins (21A, 21B) can have the same height.

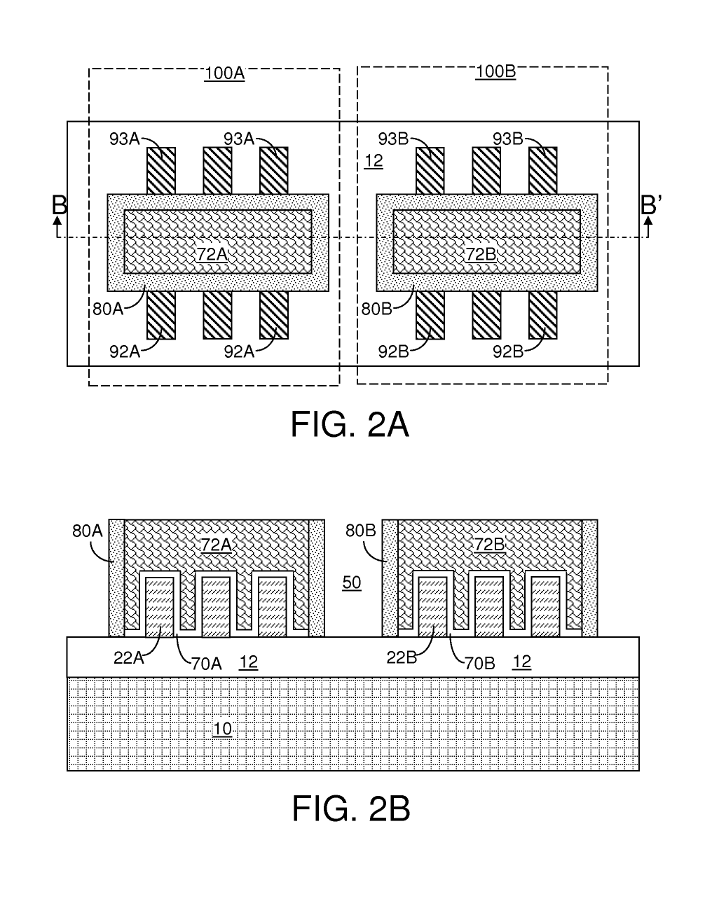

Referring to FIGS. 2A and 2B, a disposable dielectric layer and a disposable gate material layer are deposited and lithographically patterned to form disposable gate structures. In one embodiment, at least one disposable gate structure can be formed in each device region (100A, 100B). A first disposable gate structure (70A, 72A) straddles the at least one first semiconductor material portion (such as the at least one first semiconductor fin 21A shown in FIGS. 1A and 1B), and a second disposable gate structure (70B, 72B) straddles the at least one second semiconductor material portion (such as the at least one second semiconductor fin 21B shown in FIGS. 1A and 1B).

Each disposable gate structure can include a vertical stack of a disposable dielectric portion (70A or 70B) and a disposable gate material portion (72A or 72B). Each disposable dielectric portion (70A, 70B) is a remaining portion of the disposable dielectric layer after the lithographic patterning, and each disposable gate material portion (72A, 72B) is a remaining portion of the disposable gate material layer after the lithographic patterning. The disposable dielectric portions (70A, 70B) can include a dielectric material such as silicon oxide, silicon nitride, and/or silicon oxynitride. The disposable gate material portions (72A, 72B) can include a conductive material, semiconductor material, and/or a dielectric material that is different from the material of the disposable dielectric portions (70A, 70B). The conductive material can be an elemental metal or a metallic compound. The semiconductor material can be silicon, germanium, a III-V compound semiconductor material, or an alloy or a stack thereof, and the dielectric material can be silicon oxide, silicon nitride, or porous or non-porous organosilicate glass (OSG).

Dielectric gate spacers (80A, 80B) can be formed on sidewalls of each of the disposable gate structures (70A, 70B, 72A, 72B), for example, by deposition of a conformal dielectric material layer and an anisotropic etch. The dielectric gate spacers (80A, 80B) can include, for example, a first gate spacer 80A formed in the first device region 100A and a second gate spacer 80B formed in the second device region 100B.

Electrical dopants of a conductivity type can be implanted into the first and second device regions (100A, 100B) to form various source and drain regions, which can include, for example, first source regions 92A, first drain regions 93A, second source regions 92B, and second drain regions 93B. Each first source region 92A and each first drain region 93A are formed within a first semiconductor fin 21A (See FIGS. 1A and 1B). Each second source region 92B and each second drain region 93B are formed within a second semiconductor fin 21B (See FIGS. 1A and 1B). For a semiconductor fin (21A, 21B) doped with dopants of a first conductivity type (which is p-type or n-type), the conductivity type of the implanted electrical dopants can be a second conductivity type that is the opposite of the first conductivity type. For example, if the first conductivity type is p-type, the second conductivity type is n-type, and vice versa. If a semiconductor fin (21A or 21B) is intrinsic, p-type dopants or n-type dopants can be implanted to form a source region (92A or 92B) or a drain region (93A or 93B).

The formation of the various source regions and the various drain regions can be performed prior to, and/or after, formation of the various gate spacers (80A, 80B). The remaining portions of the first and second semiconductor fins (21A, 21B) constitute at least one first channel region 22A and at least one second channel region 22B, respectively. Each first channel region 22A and each second channel region 22B is a sub-portion of a semiconductor material portion that does not include any source region (92A, 92B) or any drain region (93A, 93B). As used herein, a “sub-portion” refers to a subset that is less than an entirety of an element. Within each semiconductor fin, the source region (92A or 92B), the drain region (93A or 93B), and the channel region (22A or 22B) can have the same width, i.e., the maximum lateral dimension. It is understood that the maximum lateral dimensions of the source regions (92A, 92B), the drain regions (93A, 93B), and the channel regions (22A, 22B) are measured along the widthwise direction of each semiconductor fin, i.e., along a horizontal direction perpendicular to the lengthwise direction of each semiconductor fin.

Optionally, metal semiconductor alloy portions (not shown) can be formed on the physically exposed top surface of the various source regions (92A, 92B) and the various drain regions (93A, 93B), for example, by deposition of a metal layer and an anneal that forms a metal semiconductor alloy (such as a metal silicide). Unreacted remaining portions of the metal semiconductor alloy can be removed, for example, by a wet etch.

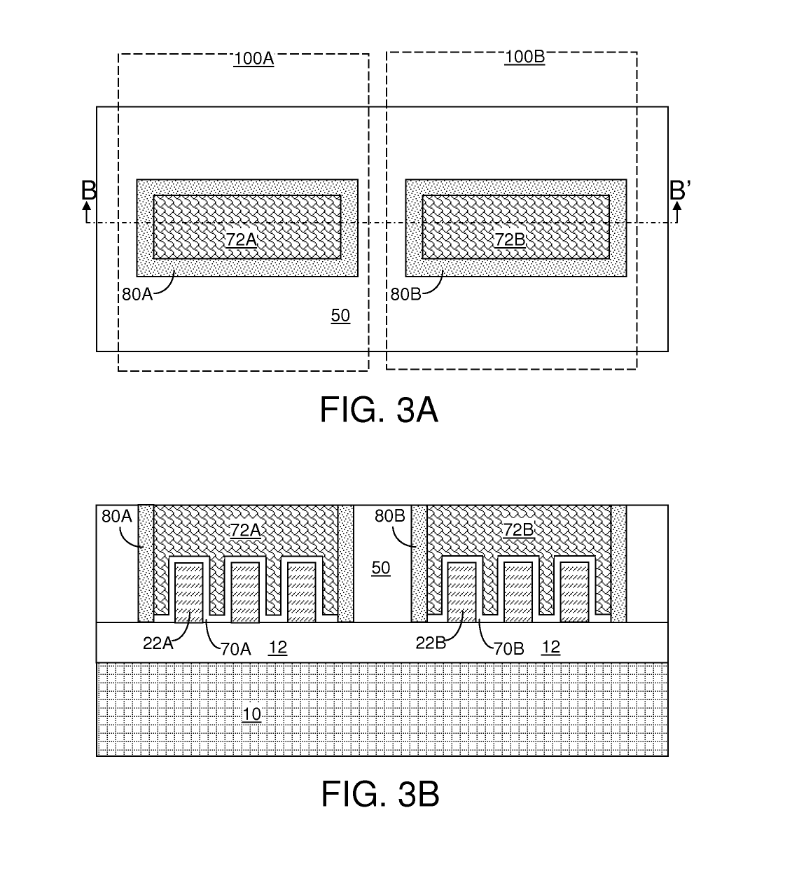

Referring to FIGS. 3A and 3B, a planarization dielectric layer 50 is deposited over the disposable gate structures (70A, 72A, 70B, 72B), the various gate spacers (80A, 80B), the various source regions (92A, 92B), and the various drain regions (93A, 93B). The planarization dielectric layer 50 includes a dielectric material, which can be a self-planarizing dielectric material such as a spin-on glass (SOG), or a non-planarizing dielectric material such as silicon oxide, silicon nitride, organosilicate glass, or combinations thereof. The planarization dielectric layer 50 is subsequently planarized, for example, by chemical mechanical planarization (CMP) such that top surfaces of the disposable gate structures (70A, 72A, 70B, 72B) become physically exposed. In one embodiment, the planarized top surface of the planarization dielectric layer 50 can be coplanar with the top surfaces of the disposable gate structures (70A, 72A, 70B, 72B). The planarization dielectric layer 50 laterally surrounds the first disposable gate structure (70A, 72A) and the second disposable gate structure (70B, 72B).

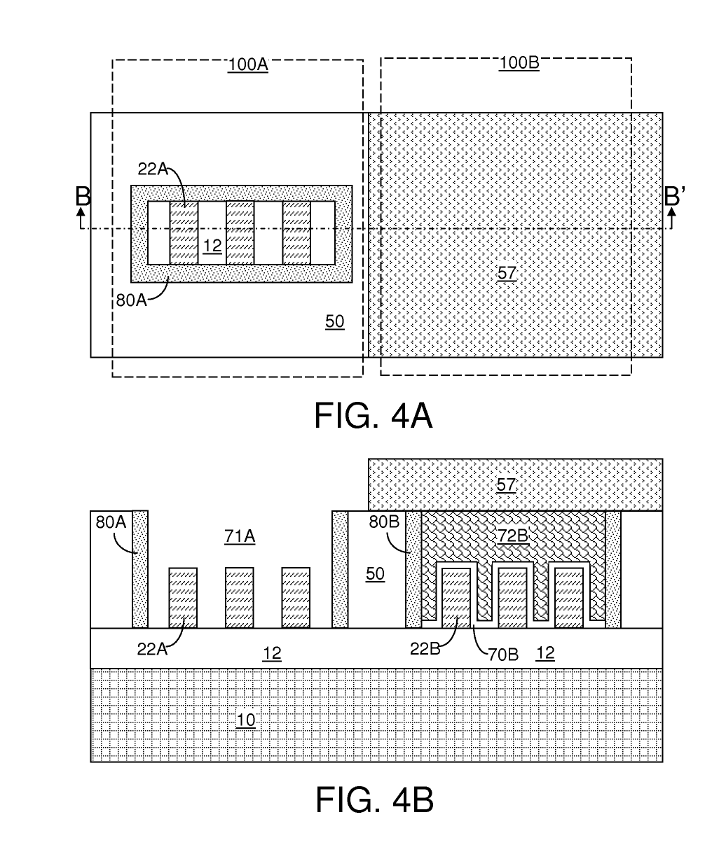

Referring to FIGS. 4A and 4B, a mask layer 57 can be formed over the planarization dielectric layer 50, and can be subsequently patterned. For example, the mask layer 57 can be patterned form an opening over the first disposable gate structure (70A, 72A) while masking the second disposable gate structure (70B, 72B). In one embodiment, that the mask layer 57 can be removed from the first device region 100A, and can be present within the second device region 100B after the patterning.

In one embodiment, the mask layer 57 is a photoresist layer that can be patterned by lithographic exposure and development. In another embodiment, the mask layer 57 can be a hard mask layer including an inorganic material, and can be patterned by applying a photoresist layer thereupon, patterning the photoresist layer, and transferring the pattern in the photoresist layer into the mask layer 57 by an etch (which can be a wet etch or a dry etch). In this case, the remaining portion of the photoresist layer can be subsequently removed.

The first disposable gate structure (70A, 72A) is removed selective to the planarization dielectric layer 50 and the first gate spacers 80A while the mask layer 57 prevents removal of underlying materials within the second device region 100B. The first disposable gate structure (70A, 72A) can be removed from underneath the opening in the mask layer 57. The removal of the first disposable gate structure (70A, 72A) can be performed, for example, by an isotropic etch such as a wet etch, or by an anisotropic etch such as a reactive ion etch. A first gate cavity 71A is formed in the space from which the first disposable gate structure (70A, 72A) is removed. A region (i.e., a sub-portion) of the first semiconductor material portion is physically exposed within the first gate cavity 71A. In one embodiment, the physically exposed region of the first semiconductor portion can be at least one first channel region 22A of the at least one first semiconductor fin (92A, 93A, 22A).

Surfaces of the first channel region 22A of each first semiconductor fin (92A, 93A, 22A) is physically exposed within the first gate cavity 71A, while surfaces of the at least one first source region 92A and surfaces of the at least one first drain region 93A are not physically exposed.

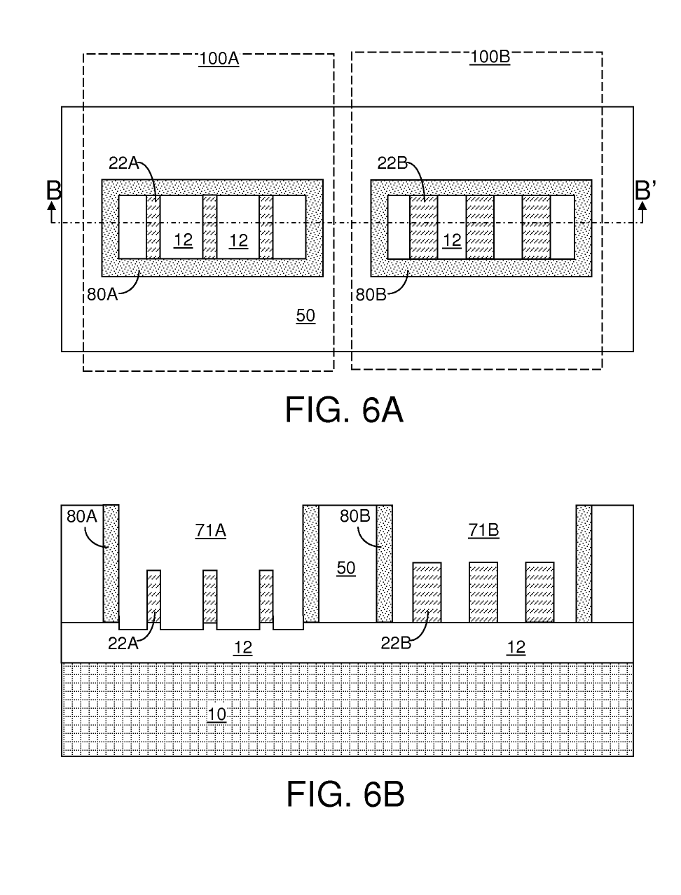

In an alternate embodiment, the disposable gate material portions (72A, 72B) can be simultaneously removed immediately after the processing steps of FIGS. 3A and 3B prior to forming the mask layer 57. In this case, an etch chemistry that is selective to the planarization dielectric layer 50, the gate spacers (80A, 80B), and the disposable dielectric portions (70A, 70B) can be employed to remove the disposable gate material portions (72A, 72B). The cavities formed by removal of the disposable gate material portions (72A, 72B) can be filled with another disposable material, which can be, for example, low quality silicon oxide, porous organosilicate glass, or non-porous organosilicate glass. Excess portions of the disposable material can be removed from above the top surface of the planarization dielectric layer 50. Low quality silicon oxide includes a high percentage (>1%) of hydrogen, and has a high etch rate in hydrofluoric acid, which is greater than the etch rate of thermal silicon oxide by a factor of 10. Low quality silicon oxide can be deposited, for example, by plasma enhanced chemical vapor deposition (PECVD) or low temperature chemical vapor deposition (LTCVD). The masking layer 57 can be subsequently formed to cover the disposable material in the second device region 100B as illustrated FIGS. 4A and 4B, and the subsequent processing steps of FIGS. 4A and 4B can be performed with adjustments to the etch chemistry to remove the disposable material portion in the first device region 100A. The disposable material portion has a higher etch rate in hydrofluoric acid based wet etch solutions, and thus, the structure illustrated in FIGS. 4A and 4B can be obtained (with the modification that the second disposable gate material portion 72B is replaced with a disposable material portion). If this alternate embodiment is employed, the etch chemistry employed at the processing steps of FIGS. 6A and 6B can be correspondingly modified to facilitate removal of the remaining disposable material portion that is present in lieu of the second disposable gate material portion 72B.

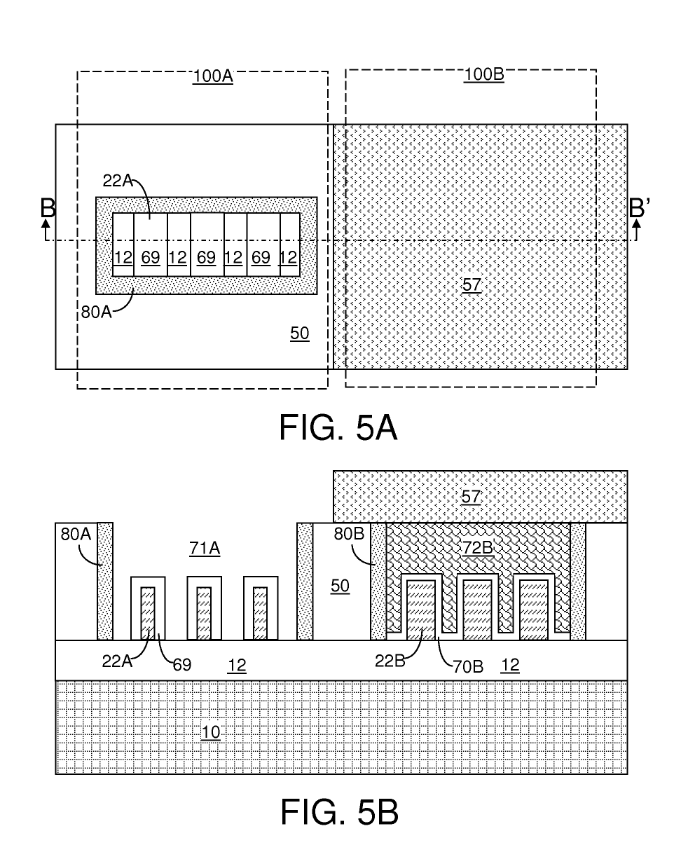

Referring to FIGS. 5A and 5B, surface portions of a sub-portion of each first semiconductor material portion within the gate cavity 71A are converted into at least one semiconductor oxide portion 69. For example, physically exposed surface portions of the at least one first semiconductor fin (92A, 93A, 22A) within the first gate cavity 71A are oxidized to form the at least one semiconductor oxide portion 69. In this case, each sub-portion of the at least one first semiconductor fin (92A, 93A, 22A) that is converted into the at least one semiconductor oxide portion 69 can be one of the at least one first channel region 22A.

Thinning of the at least one first semiconductor material portion (92A, 93A, 22A) can be effected by removing the at least one semiconductor oxide portion 69. Specifically, the at least one first semiconductor oxide portion 69 can be removed in a subsequent processing step to provide at least one thinned first semiconductor material portion, which can be at least one thinned semiconductor fin (92A, 93A, 22A).

In one embodiment, the oxidation of the surface portions of the at least one first channel region 22A can be performed by treatment of the physically exposed surfaces of the at least one first channel region 22A with a solution containing an oxidant. The oxidant can be, for example, hydrogen peroxide or any other chemical that is known to oxidize the semiconductor material of the at least one first channel region 22A. For example, the oxidation of the surface portions of the at least one first channel region 22A can be performed by a solution for forming a “chemical oxide” as known in the art. The mask layer 57 may be removed prior to oxidation by an oxidant-containing solution, or the mask layer 57 may remain during the oxidation by an oxidant-containing solution.

In another embodiment, the oxidation of the surface portions of the at least one first channel region 22A can be performed by plasma oxidation or thermal oxidation. If the mask layer 57 is a photoresist layer, the mask layer 57 is removed prior to a plasma oxidation process or a thermal oxidation process. An upper portion of the second disposable gate material portion 72B may be oxidized depending on the composition of the second disposable gate material portion 72B. If the mask layer 57 is a hard mask layer, the mask layer 57 may remain over the planarization dielectric layer 50 in the second device region 100B during the plasma oxidation process or the thermal oxidation process.

In yet another embodiment, the oxidation of the surface portions of the at least one first channel region 22A can be performed by irradiation of an ion beam including ions of an oxidizing species. An ion implantation process can be employed to irradiate the surface portions of the at least one first channel region 22A with the ions of the oxidizing species. The oxidizing species can be, for example, O₂ or O₃. The mask layer 57 may be removed prior to the irradiation with the oxidizing species, or the mask layer 57 may remain during the irradiation with the oxidizing species.

The thickness of the at least one semiconductor oxide portion 69 can be in a range from 1 nm to 5 nm, although lesser and greater thicknesses can also be employed. In one embodiment, the thickness of the at least one semiconductor oxide portion 69 can be in a range from 1.5 nm to 3.0 nm. In one embodiment, the at least one semiconductor oxide portion 69 can include silicon oxide or an oxide of a semiconductor alloy including silicon (such as a silicon germanium alloy, a silicon carbon alloy, or a silicon germanium carbon alloy).

Referring to FIGS. 6A and 6B, any remaining portion of the mask layer 57 (See FIGS. 5A and 5B) is removed selective to the planarization dielectric layer 50. The second disposable gate material portion 72B is removed selective to the planarization dielectric layer 50 by a wet etch or a dry etch. Subsequently, the at least one semiconductor oxide portion 69 and the second dielectric portion 70B can be removed, for example, by an isotropic etch. The isotropic etch can be, for example, a wet etch employing hydrofluoric acid. In one embodiment, a top surface of the planarization dielectric layer 50 may be collaterally etched during the isotropic etch, and become recessed with respect to the top surfaces of the gate spacers (80A, 80B). A second gate cavity 71B is formed in a space from which the second disposable gate structure (70B, 72B) is removed.

The combination of the oxidation process and the isotropic etch of the at least one semiconductor oxide portion 69 isotropically thins a sub-portion of each first semiconductor material portion within the first gate cavity 71A, i.e., the at least one first channel region 22A. The thinned portion of each first semiconductor material portion (i.e., each thinned first channel region 22A) has a first vertical cross-sectional shape that is invariant along the lengthwise direction of the thinned portion. Each of the at least one second semiconductor material portion (i.e., each of the at least one second semiconductor fin (92B, 93B, 22B)) has a second vertical cross-sectional shape that is invariant along the lengthwise direction of the second semiconductor material portion. Thus, each first semiconductor fin (92A, 93A, 22A) includes a thinned first channel region 22A having a lesser width than the source region 92A and the drain region 93A within the same first semiconductor fin (92A, 93A, 22A). Each second semiconductor fin (92B, 93B, 22B) has a same width throughout the entirety thereof.

In one embodiment, the processing steps of FIGS. 5A and 5B and the processing steps of FIGS. 6A and 6B can be repeatedly performed until the thinned portions of each first semiconductor fin (92A, 93A, 22A) reach a target width.

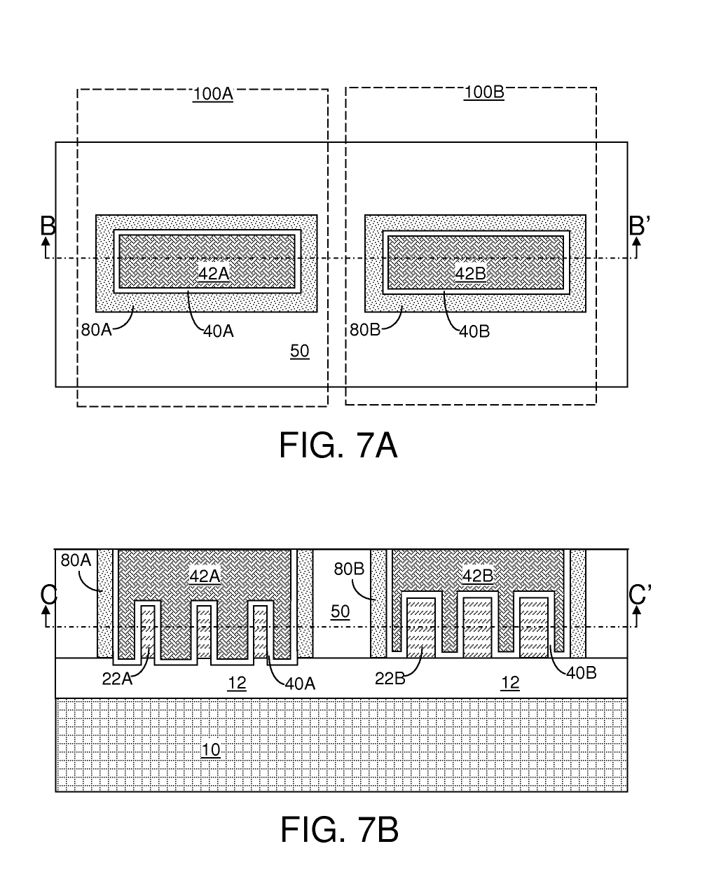

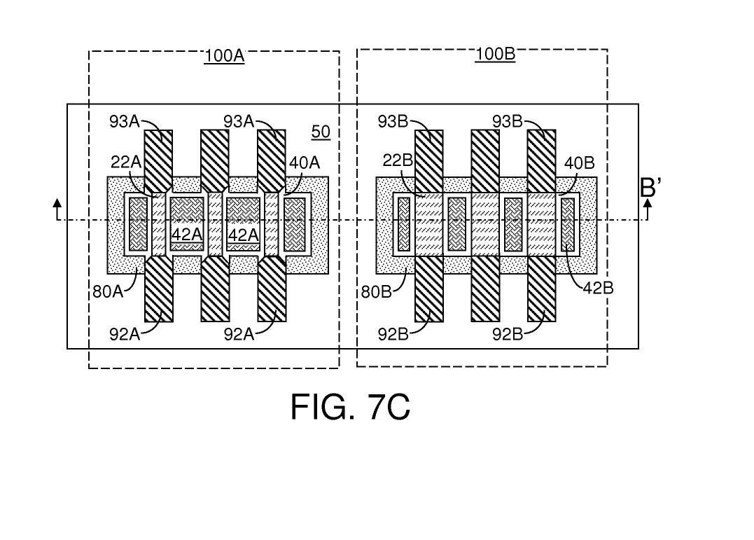

Referring to FIGS. 7A-7C, replacement gate structures are formed by filling the first and second gate cavities (71A, 71B; See FIGS. 6A and 6B) with a gate dielectric layer and a gate conductor layer, and removing excess portion of the gate dielectric layer and the gate conductor layer from above the top surface of the planarization dielectric layer 50, for example, by chemical mechanical planarization (CMP). The remaining portion of the gate dielectric layer filling the first gate cavity 71A is a first gate dielectric 40A, and the remaining portion of the gate dielectric layer filling the second gate cavity 71B is a second gate dielectric 40B. The remaining portion of the gate conductor layer filling the first gate cavity 71A is a first gate electrode 42A, and the remaining portion of the gate conductor layer filling the second gate cavity 71B is a second gate electrode 42B.

The first exemplary semiconductor structure includes a first field effect transistor formed in the first device region 100A and a second field effect transistor formed in the second device region 100B. The first and second field effect transistors are formed on a substrate (10, 12), which can be a stack of a handle substrate 10 and a buried insulator layer 12, or a bulk semiconductor substrate. The first field effect transistor includes at least one first channel region 22A having a first vertical cross-sectional shape (e.g., the shape of one of the first channel regions 22A as shown in FIG. 7B) that is invariant along the lengthwise direction of each first channel region 22A (e.g., along the direction perpendicular to the vertical plane B-B′). The second field effect transistor includes at least one second channel region 22B having a second vertical cross-sectional shape (e.g., the shape of one of the second channel regions as shown in FIG. 7B) that is invariant along the lengthwise direction of each second channel region 22B (e.g., along the direction perpendicular to the vertical plane B-B′). Within each first semiconductor fin (92A, 93A, 22A), each of the first source region 92A and the first drain region 93A includes a pair of sidewalls that are laterally spaced from each other by a greater width than the maximum lateral dimension of the first channel region 22A within the first vertical cross-sectional shape, i.e., the width of the first channel region 22A. Within each second semiconductor fin (92B, 93B, 22B), each of the second source region 92B and the second drain region 93B includes a pair of sidewalls that are laterally spaced from each other by the same width as the maximum lateral dimension of the second channel region 22B within the second vertical cross-sectional shape.

If the first vertical cross-sectional shape is a rectangle, the maximum lateral dimension of the first channel region 22A is the width of the first channel region 22A. If the second vertical cross-sectional shape is a rectangle, the maximum lateral dimension of the second channel region 22B is the width of the second channel 22B. While the present disclosure is described employing an embodiment in which the vertical cross-sectional shapes of the first channel regions 22A are rectangles, embodiments in which an anneal process or a crystallographic etch process is performed to provide a non-rectangular vertical cross-sectional shapes of the first channel regions 22A are contemplated herein. Further, while the present disclosure is described employing an embodiment in which the vertical cross-sectional shapes of the second channel regions 22B are rectangles, embodiments in which an anneal process or a crystallographic etch process is performed to provide a non-rectangular vertical cross-sectional shapes of the second channel regions 22B are contemplated herein.

The first channel region 22A is in contact with a first gate dielectric 40A, and the second channel region 22B is in contact with a second gate dielectric 40B, which can have the same composition and the same thickness as the first gate dielectric 40A. Vertical portions of the first gate dielectric 22A is in contact with the first gate spacer 80A, vertical portions of the second gate dielectric 22B is in contact with the second gate spacer 80B, which can have the same composition and thickness as the first gate spacer 80A.

The first gate dielectric 40A is in physical contact with the first channel region 22A. The first gate electrode 42A is laterally surrounded by the vertical portions of the first gate dielectric 40A that contact the first gate spacer 80A. The first vertical cross-sectional shape of the first channel region 22A can be a first rectangle, and the second vertical cross-sectional shape of the second channel region 22B can be a second rectangle.

In one embodiment, a first source region 92A and a first drain region 93A of the first field effect transistor and a second source region 92B and a second drain region 93B of the second field effect transistor can have the same width as the maximum lateral dimension of the second channel region 22B. If the second vertical cross-sectional shape of the second channel region 22B is the second rectangle, the maximum lateral dimension of the second channel region 22B is the width of the second rectangle.

In one embodiment, the oxidation of surface portions of the at least one first channel region 22A at the processing step of FIGS. 5A and 5B can be isotropic, and the at least one first channel region 22A and the at least one second channel region 22B can have the same width and the same height prior to the oxidation process at the processing step of FIGS. 5A and 5B. In this case, the difference between the maximum lateral dimension of each second channel region 22B within the second vertical cross-sectional shape and the maximum lateral dimension of the first channel region 22A within the first vertical cross-sectional shape, as measured at the processing step of FIGS. 7A-7C, is twice the difference between the height of the second rectangle and the height of the first rectangle.

In one embodiment, the first channel region 22A and the second channel region 22B can be in physical contact with the buried insulator layer 12 in the substrate (10, 12).

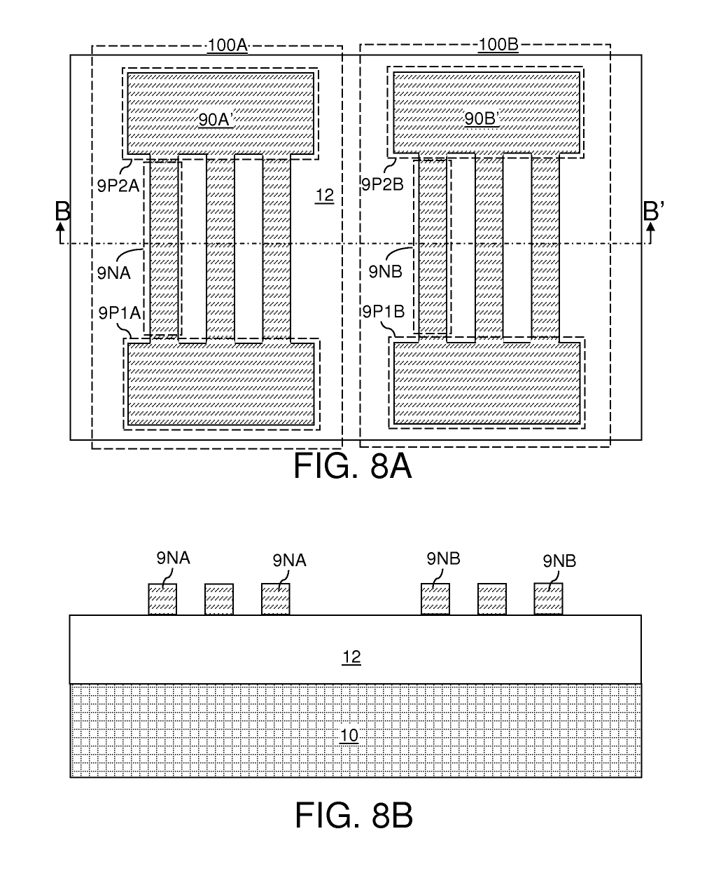

Referring to FIGS. 8A and 8B, a second exemplary semiconductor structure according to a second embodiment of the present disclosure includes a plurality of semiconductor material portions located on a substrate (10, 12). In one embodiment, the plurality of semiconductor material portions can be formed by providing a semiconductor-on-insulator (SOI) substrate including a vertical stack, from bottom to top, of a handle substrate 10, a buried insulator layer 12, and a top semiconductor layer, and by patterning the top semiconductor layer to form the plurality of semiconductor material portions. The top semiconductor layer can include a same semiconductor material throughout, or can include a plurality of regions including different semiconductor materials.

The second exemplary semiconductor structure can include various device regions. In a non-limiting illustrative example, the second exemplary semiconductor structure can include a first device region 100A and a second device region 100B. Additional device regions (not shown) can be provided for the purpose of forming additional devices. Further, multiple instances of devices can be formed in each of the device regions (100A, 100B). Each of the device regions (100A, 100B) includes at least one semiconductor nanowire. The first device region 100A can be employed to form a first nanowire field effect transistor, and the second-type device region 100B can be employed to form a second nanowire field effect transistor.

A first semiconductor material portion can be formed in the first device region 100A, and a second semiconductor material portion can be formed in the second device region 100B. In one embodiment, the first semiconductor material portion can be a first nanowire-including semiconductor portion 90A that includes at least one first semiconductor nanowire 9NA, a first source-side pad 9P1A, and a first drain-side pad 9P2A, and the second semiconductor material portion can be a second nanowire-including semiconductor portion 90B that includes at least one second semiconductor nanowire 9NB, a second source-side pad 9P1B, and a second drain-side pad 9P2B.

As used herein, a “semiconductor nanowire” refers to a semiconductor material portion having a uniform cross-sectional shape and extending along a lengthwise direction such that the maximum dimension within the uniform cross-sectional shape is less than 100 nm. In one embodiment, each semiconductor nanowire can have a rectangular horizontal cross-sectional area. As used herein, a “nanowire field effect transistor” refers to a field effect transistor in which at least a channel region is located within a semiconductor nanowire. In one embodiment, each of the first and second semiconductor nanowires (9NA, 9NB) can have a rectangular horizontal cross-sectional shape bounded by a pair of lengthwise sidewalls and a pair of widthwise sidewalls.

In one embodiment, the entirety of the each nanowire-including semiconductor portion (90A, 90B) can include a same single crystalline semiconductor material. The semiconductor material for the at least one nanowire-including semiconductor portion (90A or 90B) in each device region (100A, 100B) can be independently selected. In one embodiment, each nanowire-including semiconductor portion (90A or 90B) can include a same semiconductor material throughout the entirety of the nanowire-including semiconductor portion (90A or 90B). In one embodiment, each semiconductor material for any one of the nanowire-including semiconductor portions (90A, 90B) can be independently selected from single crystalline silicon, a single crystalline silicon-germanium alloy, a single crystalline silicon-carbon alloy, and a single crystalline silicon-germanium-carbon alloy. In one embodiment, the entirety of the top semiconductor layer can include a same single crystalline semiconductor material, and all of the nanowire-including semiconductor portions (90A, 90B) can include the same single crystalline semiconductor material.

In one embodiment, each nanowire-including semiconductor portion (90A or 90B) can include an intrinsic single crystalline semiconductor material. Alternately, one or more of the nanowire-including semiconductor portions (90A, 90B) can include a doped semiconductor material. In one embodiment, the first nanowire-including semiconductor portion 90A in the first device region 100A can be intrinsic or can have a doping of a first conductivity type, and the second nanowire-including semiconductor portion 90B in the second device region 100B can be intrinsic or can have a doping of a second conductivity type, which is the opposite of the first conductivity type. For example, the first conductivity type can be p-type and the second conductivity type can be n-type, or vice versa.

Each nanowire-including semiconductor portion (90A or 90B) can include a semiconductor material that is independently selected from silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. In one embodiment, each nanowire-including semiconductor portion (90A or 90B) can include a semiconductor material that is independently selected from single crystalline silicon, a single crystalline silicon-germanium alloy, a single crystalline silicon-carbon alloy, and a single crystalline silicon-germanium-carbon alloy. As used herein, a “semiconductor material” of an element refers to all elemental or compound semiconductor materials in the element excluding the electrical dopants therein. The semiconductor material within each nanowire-including semiconductor portion can be the same throughout the entirety of the nanowire-including semiconductor portion.

Each semiconductor nanowire (9NA, 9NB) can have a rectangular horizontal cross-sectional area. The diameter (or the lateral width is the vertical cross-sectional shape if not circular) of each semiconductor nanowire (9NA, 9NB) can be in a range from 5 nm to 300 nm, although lesser and greater thicknesses can also be employed. If each semiconductor nanowire (9NA, 9NB) has a non-circular vertical cross-sectional shape, the height of each semiconductor nanowire (9NA, 9NB) can be in a range from 30 nm to 600 nm, although lesser and greater thicknesses can also be employed. In one embodiment, the semiconductor nanowires (9NA, 9NB) can have the same diameter, the same width, and/or the same height. In one embodiment, the semiconductor nanowires (9NA, 9NB) can have the same width and the same height.

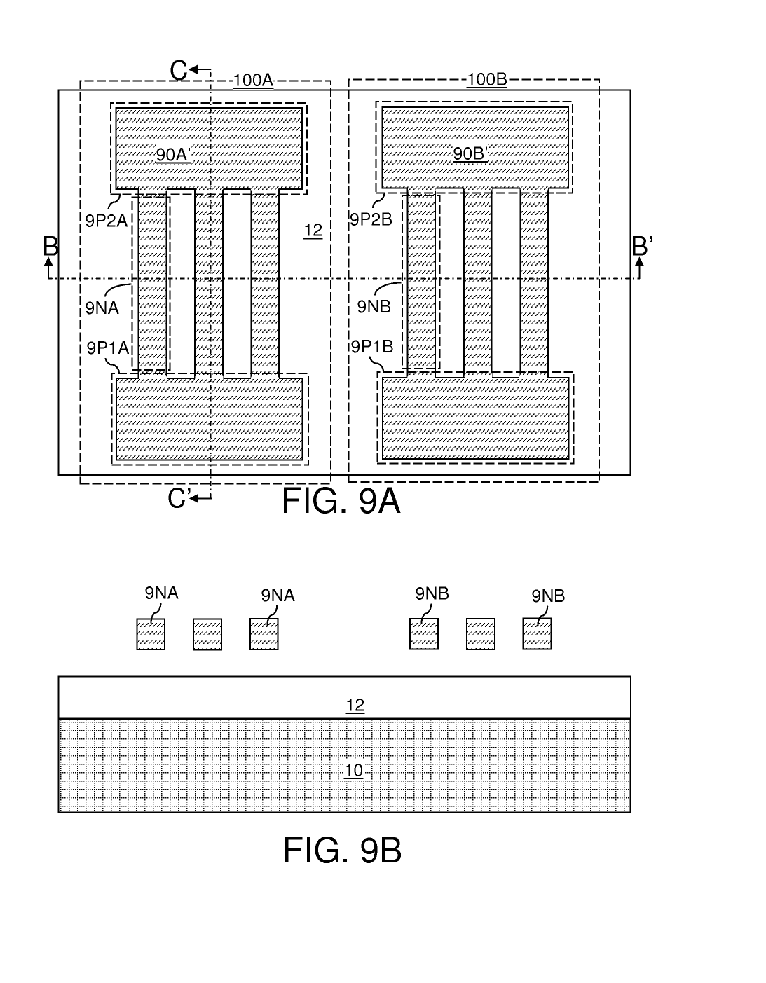

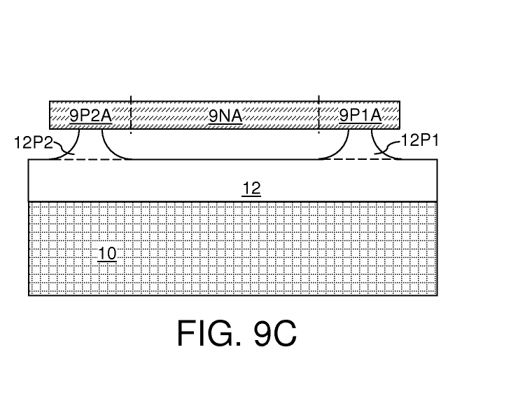

Referring to FIGS. 9A-9C, portions of the buried insulator layer 12 underlying the semiconductor nanowires (9NA, 9NB) and peripheral portions of the source-side pads (9P1A, 9P1B) and the drain-side pads (9P2A, 9P2B) are removed, for example, by an isotropic etch to suspended the semiconductor nanowires (9NA, 9NB) above a recessed surface of buried insulator layer 12. In one embodiment, the buried insulator layer 12 can include silicon oxide, and the isotropic etch can be a wet etch employing hydrofluoric acid. Each source-side pad (9P1A, 9P1B) can be mechanically supported by a first insulator pedestal portion 12P1 that protrudes above surfaces of recessed portions of the buried insulator layer 12, and each drain-side pad (9P2A, 9P2B) can be mechanically supported by a second insulator pedestal portion 12P2 that protrudes above surfaces of recessed portions of the buried insulator layer 12.

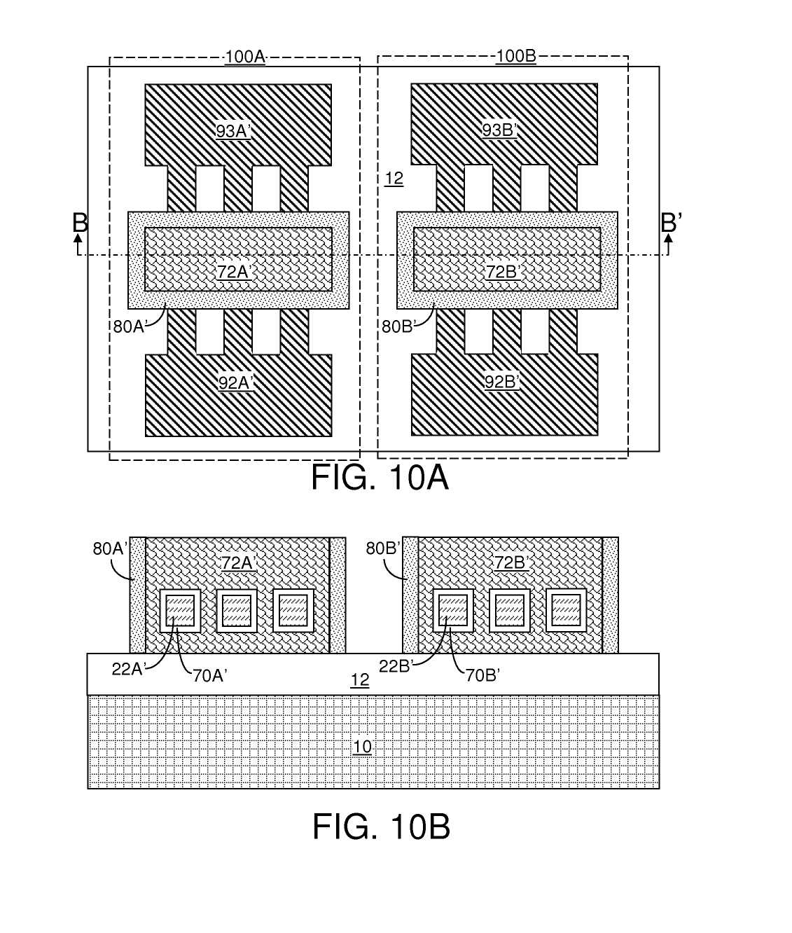

Referring to FIGS. 10A and 10B, a disposable dielectric layer and a disposable gate material layer are deposited and lithographically patterned to form disposable gate structures. In one embodiment, at least one disposable gate structure can be formed in each device region (100A, 100B). A first disposable gate structure (70A′, 72A′) straddles the first semiconductor material portion (such as the first nanowire-including semiconductor portion 90A shown in FIGS. 9A-9C), and a second disposable gate structure (70B′, 72B′) straddles the second semiconductor material portion (such as the second nanowire-including semiconductor portion 90B shown in FIGS. 9A-9C).

Each disposable gate structure can include a vertical stack of a disposable dielectric portion (70A′ or 70B′) and a disposable gate material portion (72A′ or 72B′). Each disposable dielectric portion (70A′, 70B′) is a remaining portion of the disposable dielectric layer after the lithographic patterning, and each disposable gate material portion (72A′, 72B′) is a remaining portion of the disposable gate material layer after the lithographic patterning. The disposable dielectric portions (70A′, 70B′) can include a dielectric material such as silicon oxide, silicon nitride, and/or silicon oxynitride. The disposable gate material portions (72A′, 72B′) can include a conductive material, semiconductor material, and/or a dielectric material that is different from the material of the disposable dielectric portions (70A′, 70B′). The conductive material can be an elemental metal or a metallic compound. The semiconductor material can be silicon, germanium, a III-V compound semiconductor material, or an alloy or a stack thereof, and the dielectric material can be silicon oxide, silicon nitride, or porous or non-porous organosilicate glass (OSG).

Dielectric gate spacers (80A′, 80B′) can be formed on sidewalls of each of the disposable gate structures (70A′, 70B′, 72A′, 72B′), for example, by deposition of a conformal dielectric material layer and an anisotropic etch. The dielectric gate spacers (80A′, 80B′) can include, for example, a first gate spacer 80A′ formed in the first device region 100A and a second gate spacer 80B′ formed in the second device region 100B.

Electrical dopants of a conductivity type can be implanted into the first and second device regions (100A, 100B) to form various source and drain regions, which can include, for example, first source regions 92A′, first drain regions 93A′, second source regions 92B′, and second drain regions 93B′. Each first source region 92A′ and each first drain region 93A′ are formed within a first nanowire-including semiconductor portion 90A (See FIGS. 9A-9C). Each second source region 92B′ and each second drain region 93B′ are formed within a second nanowire-including semiconductor portion 90B (See FIGS. 9A-9C). For a nanowire-including semiconductor portion (90A, 90B) doped with dopants of a first conductivity type (which is p-type or n-type), the conductivity type of the implanted electrical dopants can be a second conductivity type that is the opposite of the first conductivity type. For example, if the first conductivity type is p-type, the second conductivity type is n-type, and vice versa. If a nanowire-including semiconductor portion (90A, 90B) is intrinsic, p-type dopants or n-type dopants can be implanted to form a source region (92A′ or 92B′) or a drain region (93A′ or 93B′).

The formation of the various source regions and the various drain regions can be performed prior to, and/or after, formation of the various gate spacers (80A′, 80B′). The remaining portions of the first and second nanowire-including semiconductor portions (90A, 90B) constitute a first channel region 22A′ and a second channel region 22B′, respectively. Each first channel region 22A′ and each second channel region 22B′ is a sub-portion of a semiconductor material portion that does not include any source region (92A′, 92B′) or any drain region (93A′, 93B′). Within each semiconductor nanowire, the source region (92A′ or 92B′), the drain region (93A′ or 93B′), and the channel region (22A′ or 22B′) can have the same width, i.e., the maximum lateral dimension. It is understood that the maximum lateral dimensions of the source regions (92A′, 92B′), the drain regions (93A′, 93B′), and the channel regions (22A′, 22B′) are measured along the widthwise direction of each semiconductor nanowire, i.e., along a horizontal direction perpendicular to the lengthwise direction of each semiconductor nanowire.

Optionally, metal semiconductor alloy portions (not shown) can be formed on the physically exposed top surface of the various source regions (92A′, 92B′) and the various drain regions (93A′, 93B′), for example, by deposition of a metal layer and an anneal that forms a metal semiconductor alloy (such as a metal silicide). Unreacted remaining portions of the metal semiconductor alloy can be removed, for example, by a wet etch.

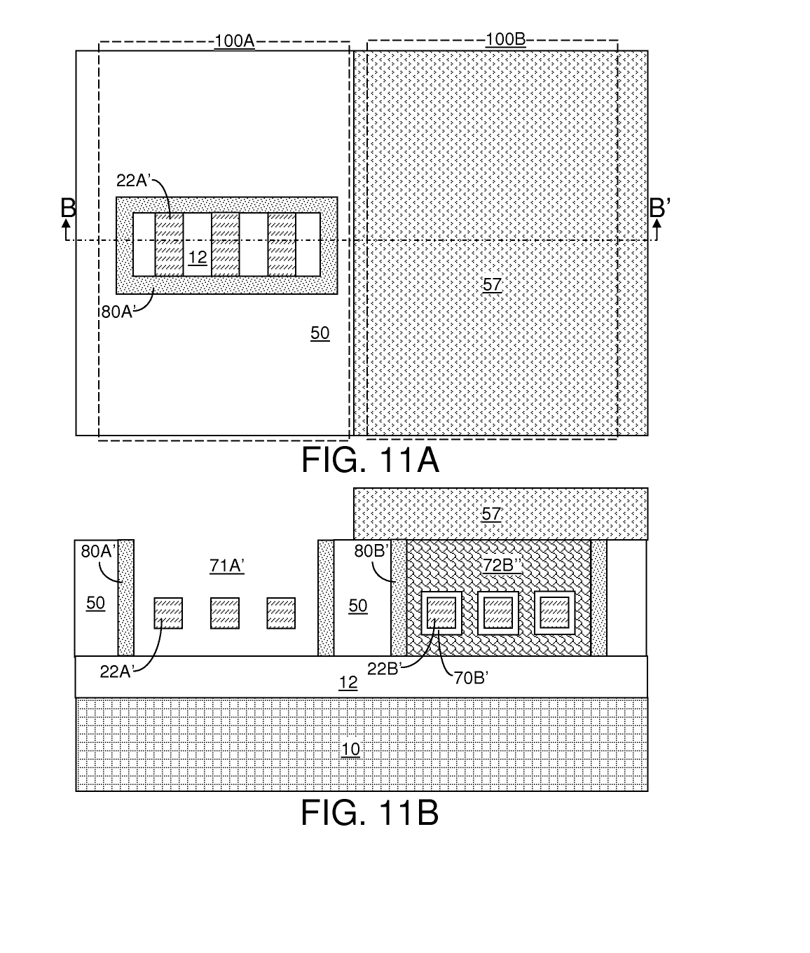

Referring to FIGS. 11A and 11B, a planarization dielectric layer 50 is deposited over the disposable gate structures (70A′, 72A′, 70B′, 72B′), the various gate spacers (80A′, 80B′), the various source regions (92A′, 92B′), and the various drain regions (93A′, 93B′) in the same manner as in the first embodiment. The planarization dielectric layer 50 includes a dielectric material, which can be a self-planarizing dielectric material such as a spin-on glass (SOG), or a non-planarizing dielectric material such as silicon oxide, silicon nitride, organosilicate glass, or combinations thereof. The planarization dielectric layer 50 is subsequently planarized, for example, by chemical mechanical planarization (CMP) such that top surfaces of the disposable gate structures (70A′, 72A′, 70B′, 72B′) become physically exposed. In one embodiment, the planarized top surface of the planarization dielectric layer 50 can be coplanar with the top surfaces of the disposable gate structures (70A′, 72A′, 70B′, 72B′). The planarization dielectric layer 50 laterally surrounds the first disposable gate structure (70A′, 72A′) and the second disposable gate structure (70B′, 72B′).

A mask layer 57 can be formed over the planarization dielectric layer 50, and can be subsequently patterned. For example, the mask layer 57 can be patterned form an opening over the first disposable gate structure (70A′, 72A′) while masking the second disposable gate structure (70B′, 72B′). In one embodiment, that the mask layer 57 can be removed from the first device region 100A, and can be present within the second device region 100B after the patterning.

In one embodiment, the mask layer 57 is a photoresist layer that can be patterned by lithographic exposure and development. In another embodiment, the mask layer 57 can be a hard mask layer including an inorganic material, and can be patterned by applying a photoresist layer thereupon, patterning the photoresist layer, and transferring the pattern in the photoresist layer into the mask layer 57 by an etch (which can be a wet etch or a dry etch). In this case, the remaining portion of the photoresist layer can be subsequently removed.

The first disposable gate structure (70A′, 72A′) is removed selective to the planarization dielectric layer 50 and the first gate spacers 80A′ while the mask layer 57 prevents removal of underlying materials within the second device region 100B. The first disposable gate structure (70A′, 72A′) can be removed from underneath the opening in the mask layer 57. The removal of the first disposable gate structure (70A′, 72A′) can be performed, for example, by an isotropic etch such as a wet etch, or by an anisotropic etch such as a reactive ion etch. A first gate cavity 71A′ is formed in the space from which the first disposable gate structure (70A′, 72A′) is removed. A region (i.e., a sub-portion) of the first semiconductor material portion is physically exposed within the first gate cavity 71A′. In one embodiment, the physically exposed region of the first semiconductor portion can be at least one first channel region 22A′ of the at least one first semiconductor nanowire.

Surfaces of the first channel region 22A′ of each first semiconductor nanowire is physically exposed within the first gate cavity 71A′, while surfaces of the at least one first source region 92A′ and surfaces of the at least one first drain region 93A′ are not physically exposed.

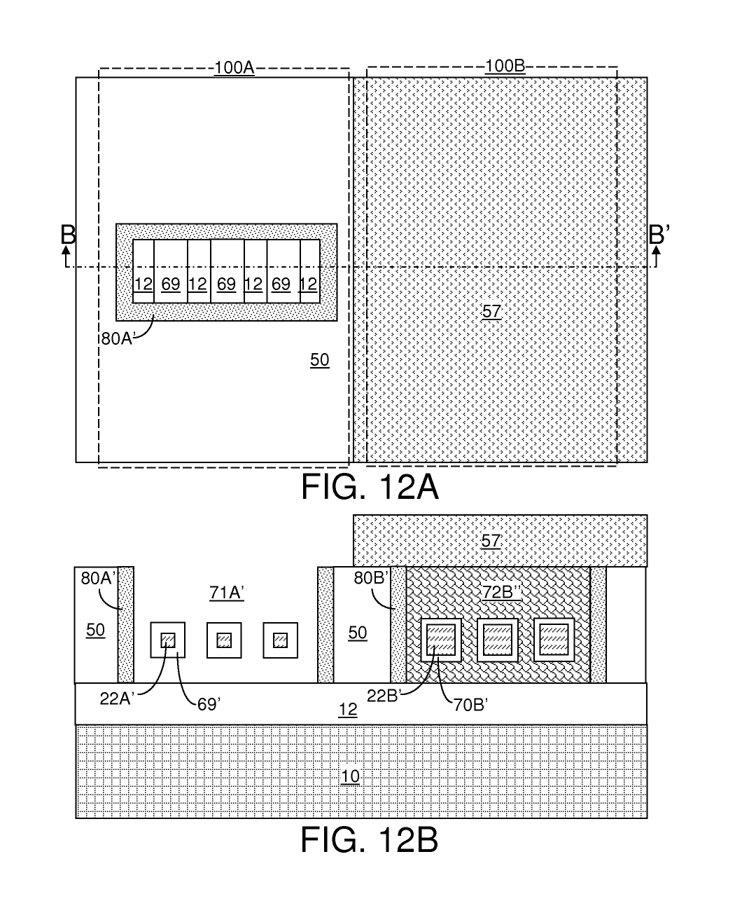

Referring to FIGS. 12A and 12B, surface portions of a sub-portion of each first semiconductor material portion within the gate cavity 71A′ are converted into at least one semiconductor oxide portion 69′. For example, physically exposed surface portions of the at least one first semiconductor nanowire within the first gate cavity 71A′ are oxidized to form the at least one semiconductor oxide portion 69′. In this case, each sub-portion of the at least one first semiconductor nanowire that is converted into the at least one semiconductor oxide portion 69′ can be one of the at least one first channel region 22A′.

Thinning of the at least one first channel region 22A′ can be effected by removing the at least one semiconductor oxide portion 69′. Specifically, the at least one first semiconductor oxide portion 69′ can be removed in a subsequent processing step to provide at least one thinned first channel region 22A′, which is a thinned portion of a first semiconductor nanowire.

In one embodiment, the oxidation of the surface portions of the at least one first channel region 22A′ can be performed by treatment of the physically exposed surfaces of the at least one first channel region 22A′ with a solution containing an oxidant. The oxidant can be, for example, hydrogen peroxide or any other chemical that is known to oxidize the semiconductor material of the at least one first channel region 22A′. For example, the oxidation of the surface portions of the at least one first channel region 22A′ can be performed by a solution for forming a “chemical oxide” as known in the art. The mask layer 57 may be removed prior to oxidation by an oxidant-containing solution, or the mask layer 57 may remain during the oxidation by an oxidant-containing solution.

In another embodiment, the oxidation of the surface portions of the at least one first channel region 22A′ can be performed by plasma oxidation or thermal oxidation. If the mask layer 57 is a photoresist layer, the mask layer 57 is removed prior to a plasma oxidation process or a thermal oxidation process. An upper portion of the second disposable gate material portion 72B′ may be oxidized depending on the composition of the second disposable gate material portion 72B′. If the mask layer 57 is a hard mask layer, the mask layer 57 may remain over the planarization dielectric layer 50 in the second device region 100B during the plasma oxidation process or the thermal oxidation process.

In yet another embodiment, the oxidation of the surface portions of the at least one first channel region 22A′ can be performed by irradiation of an ion beam including ions of an oxidizing species. An ion implantation process can be employed to irradiate the surface portions of the at least one first channel region 22A′ with the ions of the oxidizing species. The oxidizing species can be, for example, O₂ or O₃. The mask layer 57 may be removed prior to the irradiation with the oxidizing species, or the mask layer 57 may remain during the irradiation with the oxidizing species.

The thickness of the at least one semiconductor oxide portion 69′ can be in a range from 1 nm to 5 nm, although lesser and greater thicknesses can also be employed. In one embodiment, the thickness of the at least one semiconductor oxide portion 69′ can be in a range from 1.5 nm to 3.0 nm. In one embodiment, the at least one semiconductor oxide portion 69′ can include silicon oxide or an oxide of a semiconductor alloy including silicon (such as a silicon germanium alloy, a silicon carbon alloy, or a silicon germanium carbon alloy).

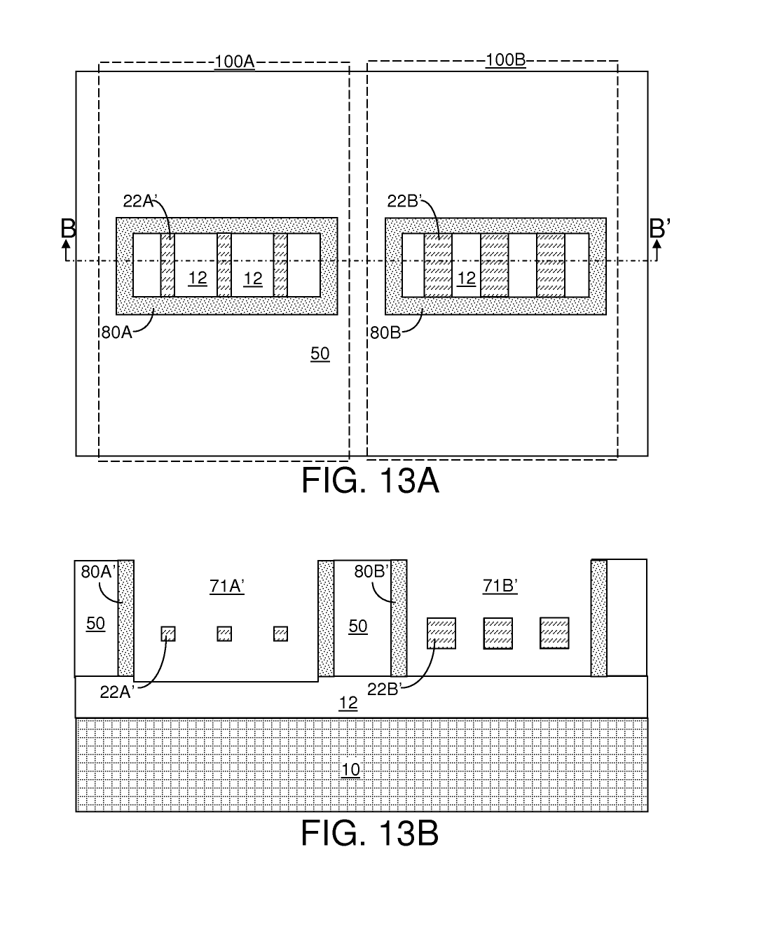

Referring to FIGS. 13A and 13B, any remaining portion of the mask layer 57 (See FIGS. 12A and 12B) is removed selective to the planarization dielectric layer 50. The second disposable gate material portion 72B′ is removed selective to the planarization dielectric layer 50 by a wet etch or a dry etch. Subsequently, the at least one semiconductor oxide portion 69′ and the second dielectric portion 70B′ can be removed, for example, by an isotropic etch. The isotropic etch can be, for example, a wet etch employing hydrofluoric acid. In one embodiment, a top surface of the planarization dielectric layer 50 may be collaterally etched during the isotropic etch, and become recessed with respect to the top surfaces of the gate spacers (80A′, 80B′). A second gate cavity 71B′ is formed in a space from which the second disposable gate structure (70B′, 72B′) is removed.

The combination of the oxidation process and the isotropic etch of the at least one semiconductor oxide portion 69′ isotropically thins a sub-portion of each first semiconductor material portion within the first gate cavity 71A′, i.e., the at least one first channel region 22A′. The thinned portion of each first semiconductor material portion (i.e., each thinned first channel region 22A′) has a first vertical cross-sectional shape that is invariant along the lengthwise direction of the thinned portion. Each semiconductor nanowire within the second semiconductor material portion (92B′, 93B′, 22B′) has a second vertical cross-sectional shape that is invariant along the lengthwise direction of the second semiconductor material portion. Thus, each first semiconductor nanowire includes a thinned first channel region 22A′ having a lesser width than the portion of the source region 92A′ and the portion of the drain region 93A′ within the same first semiconductor nanowire. Each second semiconductor nanowire has a same width throughout the entirety thereof.

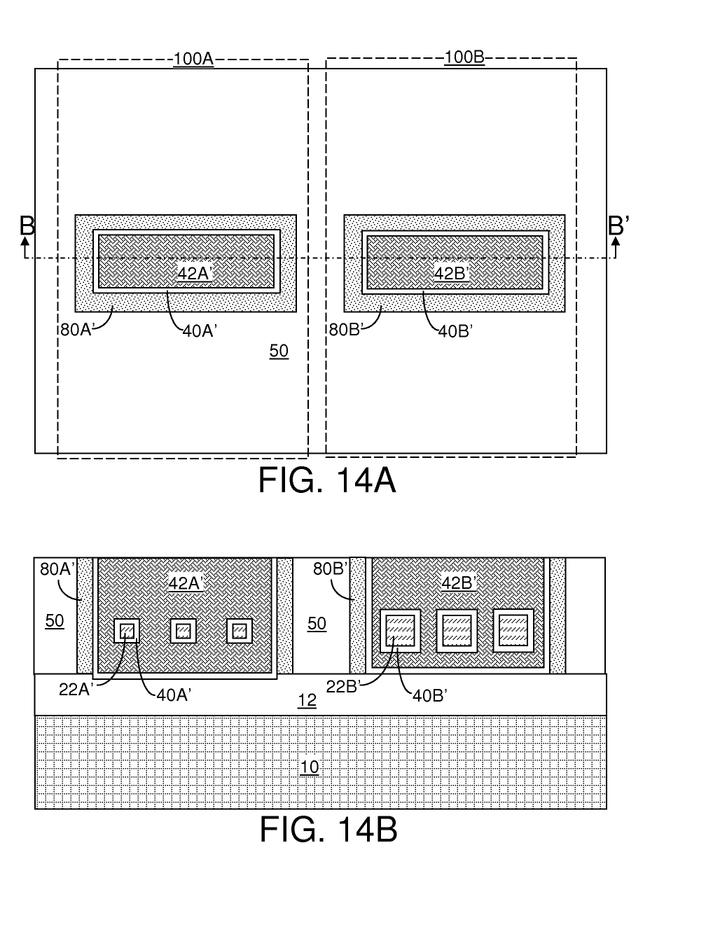

Referring to FIGS. 14A-14C, replacement gate structures are formed by filling the first and second gate cavities (71A′, 71B′; See FIGS. 13A and 13B) with a gate dielectric layer and a gate conductor layer, and removing excess portion of the gate dielectric layer and the gate conductor layer from above the top surface of the planarization dielectric layer 50, for example, by chemical mechanical planarization (CMP). The remaining portion of the gate dielectric layer filling the first gate cavity 71A′ is a first gate dielectric 40A′, and the remaining portion of the gate dielectric layer filling the second gate cavity 71B′ is a second gate dielectric 40B′. The remaining portion of the gate conductor layer filling the first gate cavity 71A′ is a first gate electrode 42A′, and the remaining portion of the gate conductor layer filling the second gate cavity 71B′ is a second gate electrode 42B′.

The second exemplary semiconductor structure includes a first field effect transistor formed in the first device region 100A and a second field effect transistor formed in the second device region 100B. The first and second field effect transistors are formed on a substrate (10, 12), which can be a stack of a handle substrate 10 and a buried insulator layer 12. The first field effect transistor includes at least one first channel region 22A′ having a first vertical cross-sectional shape (e.g., the shape of one of the first channel regions 22A′ as shown in FIG. 14B) that is invariant along the lengthwise direction of each first channel region 22A′ (e.g., along the direction perpendicular to the vertical plane B-B′). The second field effect transistor includes at least one second channel region 22B′ having a second vertical cross-sectional shape (e.g., the shape of one of the second channel regions as shown in FIG. 7B) that is invariant along the lengthwise direction of each second channel region 22B′ (e.g., along the direction perpendicular to the vertical plane B-B′). Within each first semiconductor nanowire, each of the portion of the first source region 92A′ and the portion of the first drain region 93A′ includes a pair of sidewalls that are laterally spaced from each other by a greater width than the maximum lateral dimension of the first channel region 22A′ within the first vertical cross-sectional shape, i.e., the width of the first channel region 22A′. Within each second semiconductor nanowire, each of the portion of the second source region 92B′ and the portion of the second drain region 93B′ includes a pair of sidewalls that are laterally spaced from each other by the same width as the maximum lateral dimension of the second channel region 22B′ within the second vertical cross-sectional shape.

If the first vertical cross-sectional shape is a rectangle, the maximum lateral dimension of the first channel region 22A′ is the width of the first channel region 22A′. If the second vertical cross-sectional shape is a rectangle, the maximum lateral dimension of the second channel region 22B′ is the width of the second channel 22B′. While the present disclosure is described employing an embodiment in which the vertical cross-sectional shapes of the first channel regions 22A′ are rectangles, embodiments in which an anneal process or a crystallographic etch process is performed to provide a non-rectangular vertical cross-sectional shapes of the first channel regions 22A′ are contemplated herein. Further, while the present disclosure is described employing an embodiment in which the vertical cross-sectional shapes of the second channel regions 22B′ are rectangles, embodiments in which an anneal process or a crystallographic etch process is performed to provide a non-rectangular vertical cross-sectional shapes of the second channel regions 22B′ are contemplated herein.

The first channel region 22A′ is in contact with a first gate dielectric 40A′, and the second channel region 22B′ is in contact with a second gate dielectric 40B′, which can have the same composition and the same thickness as the first gate dielectric 40A′. Vertical portions of the first gate dielectric 22A′ is in contact with the first gate spacer 80A′, vertical portions of the second gate dielectric 22B′ is in contact with the second gate spacer 80B′, which can have the same composition and thickness as the first gate spacer 80A′.

The first gate dielectric 40A′ is in physical contact with the first channel region 22A′. The first gate electrode 42A′ is laterally surrounded by the vertical portions of the first gate dielectric 40A′ that contact the first gate spacer 80A′. The first vertical cross-sectional shape of the first channel region 22A′ can be a first rectangle, and the second vertical cross-sectional shape of the second channel region 22B′ can be a second rectangle.

In one embodiment, a portion of the first source region 92A′ and a portion of the first drain region 93A′ of the first field effect transistor and a portion of the second source region 92B′ and a portion of the second drain region 93B′ of the second field effect transistor can have the same width as the maximum lateral dimension of the second channel region 22B′. If the second vertical cross-sectional shape of the second channel region 22B′ is the second rectangle, the maximum lateral dimension of the second channel region 22B′ is the width of the second rectangle.

A bottom surface of each first channel region 22A′ can be in physical contact with the first gate dielectric 40A′, and a bottom surface of each second channel region 22B′ can be in physical contact with the second gate dielectric 40B′, which can have the same thickness and the same composition as the first gate dielectric 40A′.

In one embodiment, the oxidation of surface portions of the at least one first channel region 22A′ at the processing step of FIGS. 12A and 12B can be isotropic, and the at least one first channel region 22A′ and the at least one second channel region 22B′ can have the same width and the same height prior to the oxidation process at the processing step of FIGS. 12A and 12B. In this case, the difference between the maximum lateral dimension of a second channel region 22B′ within a second vertical cross-sectional shape and the maximum lateral dimension of a first channel region 22A′ within a first vertical cross-sectional shape, as measured at the processing step of FIGS. 14A and 14B, can be the same as the difference between the height of the second rectangle and the height of the first rectangle, which can be the same as twice the thickness of the semiconductor material lost by the combination of oxidation and etch within the first gate cavity 71A′ (See FIGS. 12B and 13B).

The various embodiments of the present disclosure enable formation of channel regions having different dimensions without resorting to direct lithographic patterning of the dimensions of the channel regions. As such, multiple field effect transistors having different channel widths can be formed on a same substrate to provide different threshold voltages and associated variations in other devices performance metrics. Diverse field effect transistors provided on the same substrate can be advantageously employed to form advanced semiconductor circuits employing field effect transistors having different characteristics.

While the present disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the present disclosure is intended to encompass all such alternatives, modifications and variations which fall within the scope and spirit of the present disclosure and the following claims.

What is claimed is:

1. A method of forming a semiconductor structure comprising:
forming a first semiconductor material portion and a second semiconductor material portion on a substrate;
forming a first disposable gate structure straddling said first semiconductor material portion and a second disposable gate structure straddling said second semiconductor material portion;
forming a planarization dielectric layer laterally surrounding said first disposable gate structure and said second disposable gate structure;
removing said first disposable gate structure to form a gate cavity while said second disposable gate structure is not removed, wherein a region of said first semiconductor material portion is physically exposed within said gate cavity;
thinning a sub-portion of said first semiconductor material portion within said gate cavity;
removing said second disposable gate structure; and
forming gate dielectrics and gate electrodes on said thinned region of said first semiconductor material portion and said second semiconductor material portion.

2. The method of claim 1, wherein said thinning of said first semiconductor material portion is effected by:
converting surface portions of said sub-portion of said first semiconductor material portion within said gate cavity into semiconductor oxide portions; and
removing said semiconductor oxide portions.

3. The method of claim 2, wherein said semiconductor oxide portions are formed by treatment of physically exposed surfaces with a solution containing an oxidant.

4. The method of claim 2, wherein said semiconductor oxide portions are formed by plasma oxidation or thermal oxidation.

5. The method of claim 2, wherein said semiconductor oxide portions are formed by irradiation of an ion beam including ions of an oxidizing species.

6. The method of claim 1, further comprising:
forming a mask layer over said planarization dielectric layer; and
patterning said mask layer to form an opening over said first disposable gate structure while masking said second disposable gate structure, wherein said first disposable gate structure is removed from underneath said opening in said mask layer.

7. The method of claim 1, wherein a thinned portion of said first semiconductor material portion has a first vertical cross-sectional shape that is invariant along a lengthwise direction of said thinned portion, and said second semiconductor material portion has a second vertical cross-sectional shape that is invariant along a lengthwise direction of said second semiconductor material portion.

8. The method of claim 7, further comprising forming a source region and a drain region in said first semiconductor material portion, wherein a remaining region between said source region and said drain region is said sub-portion of said first semiconductor material portion.

9. The method of claim 7, wherein each of said first semiconductor material portion and said second semiconductor material portion is a semiconductor fin.

10. The method of claim 7, wherein each of said first semiconductor material portion and said second semiconductor material portion comprises a semiconductor nanowire that is suspended above a top surface of an insulator layer in said substrate prior to forming said first and second disposable gate structures.

11. A semiconductor structure including a first field effect transistor and a second field effect transistor that are located on a substrate, wherein a channel region of said first field effect transistor has a first vertical cross-sectional shape that is invariant along a lengthwise direction of said channel region of said first field effect transistor, a channel region of said second field effect transistor has a second vertical cross-sectional shape that is invariant along a lengthwise direction of said channel region of said second field effect transistor, wherein each of a source region and a drain region of said first field effect transistor comprises a pair of sidewalls that are laterally spaced from each other by a greater width than a maximum lateral dimension of said first channel region within said first vertical cross-sectional shape, and each of a source region and a drain region of said second field effect transistor comprises another pair of sidewalls that are laterally spaced from each other by a same width as a maximum lateral dimension of said channel region of said second field effect transistor within said second vertical cross-sectional shape.

12. The semiconductor structure of claim 11, wherein said channel region of said first field effect transistor is in contact with a first gate dielectric, and said channel region of said second field effect transistor is in contact with a second gate dielectric having a same composition as said first gate dielectric.

13. The semiconductor structure of claim 12, wherein vertical portions of said first gate dielectric is in contact with a first gate spacer, vertical portions of said second gate dielectric is in contact with a second gate spacer having a same composition as said first gate spacer.

14. The semiconductor structure of claim 11, wherein said
a gate dielectric contacting said channel region of said first field effect transistor;
a gate electrode laterally surrounded by said gate dielectric; and
a gate spacer contacting vertical portions of said gate dielectric.

15. The semiconductor structure of claim 11, wherein said first vertical cross-sectional shape is a first rectangle, and said second vertical cross-sectional shape is a second rectangle.

16. The semiconductor structure of claim 15, wherein said source region and said drain region of said first field effect transistor and said source region and said drain region of said second field effect transistor have a same width as said maximum lateral dimension of said channel region of said second field effect transistor.

17. The semiconductor structure of claim 15, wherein a difference between said maximum lateral dimension of said channel region of said second field effect transistor within said second vertical cross-sectional shape and said maximum lateral dimension of said channel region of said first field effect transistor within said first vertical cross-sectional shape is twice a difference between a height of said second rectangle and a height of said first rectangle.

18. The semiconductor structure of claim 15, wherein said channel region of said first field effect transistor and said channel region of said second field effect transistor are in physical contact with a buried insulator layer in said substrate.

19. The semiconductor structure of claim 15, wherein a difference between said maximum lateral dimension of said channel region of said second field effect transistor within said second vertical cross-sectional shape and said maximum lateral dimension of said channel region of said first field effect transistor within said first vertical cross-sectional shape is the same as a difference between a height of said second rectangle and a height of said first rectangle.

20. The semiconductor structure of claim 15, wherein a bottom surface of said channel region of said first field effect transistor is in physical contact with a first gate dielectric, and a bottom surface of said channel region of said second field effect transistor is in physical contact with a second gate dielectric having a same composition as said first gate dielectric.
